(19) United States
(12) Patent Application Publication
(10) Pub. No.: US 2018/0123555 A1
(43) Pub. Date: May 3, 2018

(54) FILTER INCLUDING BULK ACOUSTIC WAVE RESONATOR

(71) Applicant: Samsung Electro-Mechanics Co., Ltd., Suwon-si (KR)

(72) Inventor: June Kyoo LEE, Suwon-si (KR)

(73) Assignee: Samsung Electro-Mechanics Co., Ltd., Suwon-si (KR)

(21) Appl. No.: 15/709,764

(22) Filed: Sep. 20, 2017

(30) Foreign Application Priority Data
Oct. 31, 2016 (KR) 10-2016-0143705
Apr. 11, 2017 (KR) 10-2017-0046859

(51) Int. Cl. H03H 9/02; H03H 9/54; H03H 9/60

(52) U.S. Cl. CPC H03H 9/02086; H03H 9/02015; H03H 9/605; H03H 9/54; H03H 9/02543

(57) ABSTRACT

A filter includes: a series resonator group; and a shunt resonator group disposed between the series resonator group and a ground, wherein either one or both of the series resonator group and the shunt resonator group includes a first resonator and a second resonator connected to each other in a state in which C axis directions of the first resonator and the second resonator are opposite to each other, a third resonator connected to the first resonator in series, and a fourth resonator connected to the second resonator in series.

### CROSS-REFERENCE TO RELATED APPLICATIONS

This application claims the benefit under 35 U.S.C. § 119(a) of Korean Patent Application Nos. 10-2016-0143705 and 10-2017-0046859 filed on Oct. 31, 2016 and Apr. 11, 2017, respectively, in the Korean Intellectual Property Office, the entire disclosures of which are incorporated herein by reference for all purposes.

### BACKGROUND

### 1. Field

The following description relates to a filter including a bulk acoustic wave resonator.

### 2. Description of Related Art

Recently, in accordance with the rapid development of mobile communications devices, chemical and biological devices, and the like, a demand for a small, light filter, an oscillator, a resonant element, or an acoustic resonant mass sensor used in such devices has also increased.

A film bulk acoustic resonator (FBAR) is a device known to implement such a small, light filter, oscillator, resonant element, or acoustic resonant mass sensor. The film bulk acoustic wave resonator may be mass-produced at a minimal cost, and may be implemented to have a subminiature size. In addition, the FBAR may implement a high quality factor (Q) value, which is a main characteristic of a filter, may be used even in a microwave frequency band, and may be used in bands of a personal communications system (PCS) and a digital cordless system (DCS).

In general, an FBAR includes a resonant part implemented by sequentially stacking a first electrode, a piezoelectric layer, and a second electrode on a substrate. In operation of the FBAR, an electric field is induced in the piezoelectric layer by electrical energy applied to the first and second electrodes, and a piezoelectric phenomenon occurs in the piezoelectric layer by the induced electric field, such that the resonant part vibrates in a predetermined direction. As a result, a bulk acoustic wave is generated in the same direction as the direction in which the resonant part vibrates, thereby resulting in resonance.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a filter includes: a series resonator group; and a shunt resonator group disposed between the series resonator group and a ground, wherein either one or both of the series resonator group and the shunt resonator group includes a first resonator and a second resonator connected to each other in a state in which C axis directions of the first resonator and the second resonator are opposite to each other, a third resonator connected to the first resonator in series, and a fourth resonator connected to the second resonator in series.

The first resonator and the third resonator may be connected to the second resonator and the fourth resonator in parallel.

The first resonator and the third resonator may be connected to each other in anti-series.

A size of the first resonator and a size of the third resonator may be substantially the same.

The second resonator and the fourth resonator may be connected to each other in anti-series.

A size of the second resonator and a size of the fourth resonator may be substantially the same.

A size of the first resonator and a size of the second resonator may be substantially the same.

The series resonator group may be connected between a signal input terminal and a signal output terminal.

In another general aspect, a filter includes: a series resonator group; and a shunt resonator group disposed between the series resonator group and a ground, wherein either one or both of the series resonator group and the shunt resonator group includes a first resonator and a second resonator connected to each other in a state in which C axis directions of the first resonator and the second resonator are opposite to each other, a third resonator connected to the first resonator in parallel, and a fourth resonator connected to the second resonator in parallel.

The first resonator and the third resonator may be connected to the second resonator and the fourth resonator in series.

The first resonator and the third resonator may be connected to each other in anti-parallel.

A size of the first resonator and a size of the third resonator may be substantially the same.

The second resonator and the fourth resonator may be connected to each other in anti-parallel.

A size of the second resonator and a size of the fourth resonator may be substantially the same.

A size of the first resonator and a size of the second resonator may be substantially the same.

The series resonator group may be connected between a signal input terminal and a signal output terminal.

Other features and aspects will be apparent from the following detailed description, the drawings, and the claims.

### BRIEF DESCRIPTION OF DRAWINGS

FIG. 1 is a cross-sectional view illustrating a bulk acoustic wave resonator, according to an embodiment.

FIG. 2 is a schematic circuit diagram illustrating a filter, according to an embodiment.

FIG. 3 is a circuit diagram illustrating bulk acoustic wave resonators connected to each other in anti-parallel, according to an embodiment.

FIG. 4 is a circuit diagram illustrating bulk acoustic wave resonators connected to each other in anti-series, according to an embodiment.

FIG. 5 is a circuit diagram illustrating a series resonator group, according to an embodiment.

FIG. 6 is a circuit diagram illustrating a series resonator group, according to another embodiment.

FIG. 7 is a circuit diagram illustrating a shunt resonator group, according to an embodiment.

FIG. 8 is a circuit diagram illustrating a shunt resonator group, according to another embodiment.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

Hereinafter, example embodiments will be described in detail with reference to the accompanying drawings.

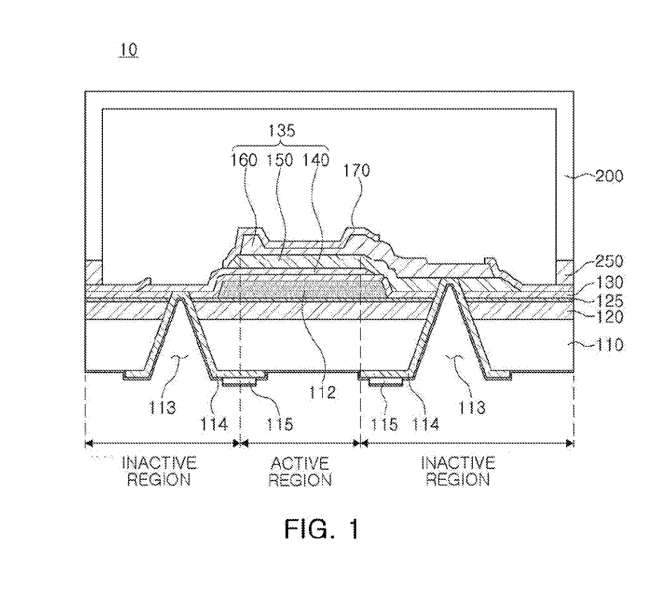

FIG. 1 is a cross-sectional view illustrating a bulk acoustic wave resonator 10, according to an embodiment.

Referring to FIG. 1, the bulk acoustic wave resonator 10 is a film bulk acoustic resonator (FBAR). The bulk acoustic wave resonator 10 includes a multilayer structure including a substrate 110, an insulating layer 120, an air cavity 112, and a resonant part 135, and a cap 200 coupled to the multilayer structure.

The substrate 110 may be a silicon substrate, and the insulating layer 120, which electrically isolates the resonant part 135 from the substrate 110, is disposed on an upper surface of the substrate 110. The insulating layer 120 may be formed on the substrate 110 by performing chemical vapor deposition, radio frequency (RF) magnetron sputtering, or evaporation using silicon dioxide (SiO₂) or aluminum oxide (Al₂O₃).

The air cavity 112 is positioned above the insulating layer 120. The air cavity 112 is positioned below the resonant part 135 so that the resonant part 135 may vibrate in a predetermined direction. The air cavity 112 may be formed by a process of forming an air cavity sacrificial layer pattern on the insulating layer 120, forming a membrane 130 on the air cavity sacrificial layer pattern, and then etching and removing the air cavity sacrificial layer pattern. The membrane 130 is, for example, an oxidation protecting film or a protective layer protecting the substrate 110.

An etch stop layer 125 is additionally formed between the insulating layer 120 and the air cavity 112. The etch stop layer 125 protects the substrate 110 and the insulating layer 120 from an etching process, and is a base supporting the etch stop layer 125 and enabling the depositing of several different layers on the etch stop layer 125.

The resonant part 135 includes a first electrode 140, a piezoelectric layer 150, and a second electrode 160 sequentially stacked on the membrane 130. A common region in which the first electrode 140, the piezoelectric layer 150, and the second electrode 160 overlap one another in a vertical direction is positioned above the air cavity 112. The first electrode 140 and the second electrode 160 may be formed of any one of gold (Au), titanium (Ti), tantalum (Ta), molybdenum (Mo), ruthenium (Ru), platinum (Pt), tungsten (W), aluminum (Al), iridium (Ir), and nickel (Ni), or alloys thereof.

The piezoelectric layer 150, which generates a piezoelectric effect in which electrical energy is converted into mechanical energy having an elastic wave form, may be formed of any one of aluminum nitride (AlN), zinc oxide (ZnO), and lead zirconium titanium oxide (PZT; PbZrTiO). In addition, the piezoelectric layer 150 may further include a rare earth metal. As an example, the rare earth metal includes any one or any combination of any two or more of scandium (Sc), erbium (Er), yttrium (Y), and lanthanum (La). Additionally, the piezoelectric layer 150 may include 1 to 20 at % of a rare earth metal.

Additionally, a seed layer for improving crystal alignment of the piezoelectric layer 150 may be disposed below the first electrode 140. The seed layer may be formed of any one of aluminum nitride (AlN), zinc oxide (ZnO), and lead zirconium titanium oxide (PZT; PbZrTiO) having a same crystallinity as a crystallinity of the piezoelectric layer 150.

The resonant part 135 includes an active region and an inactive region. The active region of the resonant part 135, which is a region that vibrates and resonates in a predetermined direction by a piezoelectric phenomenon generated in the piezoelectric layer 150 when electrical energy, such as a radio frequency signal, is applied to the first electrode 140 and the second electrode 160, corresponds to a region in which the first electrode 140, the piezoelectric layer 150, and the second electrode 160 overlap one another in the vertical direction above the air cavity 112. The inactive region of the resonant part 135, which is a region that does not resonate by the piezoelectric phenomenon even when the electrical energy is applied to the first and second electrodes 140 and 160, is a region outside the active region.

The resonant part 135 outputs a radio frequency signal having a specific frequency using the piezoelectric phenomenon. In detail, the resonant part 135 outputs a radio frequency signal having a resonant frequency corresponding to vibrations depending on the piezoelectric phenomenon of the piezoelectric layer 150.

A protective layer 170 is disposed on the second electrode 160 to prevent the second electrode 160 from being externally exposed. The protective layer 170 is also disposed on the membrane 130, the first electrode 140, and the piezoelectric layer 150. The protective layer 170 may be formed of any one of a silicon oxide-based insulating material, a silicon nitride-based insulating material, and an aluminum nitride-based insulating material. Although an example in which one multilayer structure is accommodated in one cap 200 is illustrated in FIG. 1, multiple multilayer structures may be accommodated in one cap 200, and may be connected to each other depending on a design. In an example including multiple multilayer structures connected to each other, the multilayer structures may include externally exposed wiring electrodes formed on the first and second electrodes 140 and 160 to be connected to each other.

The cap 200 is bonded to the multilayer structure, and protects the resonant part 135 from an external environment. The cap 200 has a cover form including an internal space in which the resonant part 135 is accommodated. For example, the cap 200 includes an accommodating part formed at the center of the cap 200 so as to accommodate the resonant part 135 therein, and is coupled to the multilayer structure at an edge of the multilayer structure. The edge of the cap 200 is directly or indirectly bonded to the substrate 110 by an adhesive 250 in a specific region. Although an example in which the cap 200 is bonded to the protective layer 170 stacked on the substrate 110 is illustrated in FIG. 1, the cap 200 may penetrate through the protective layer 170 and may be bonded to any one or any combination of any two or more of the membrane 130, the etch stop layer 125, the insulating layer 120, and the substrate 110.

The cap 200 is, for example, bonded to the substrate 110 by eutectic bonding. In this example, the cap 200 is bonded to the substrate 110 by depositing the adhesive 250 that may be eutectically bonded to the substrate 110 on the multilayer structure and then pressing and heating a substrate wafer and a cap wafer. The adhesive 250 may include a eutectic material of copper (Cu)-tin (Sn), and may include a solder ball.

At least one via hole 113 penetrating through the substrate 110 in a thickness direction is formed in a lower surface of the substrate 110. The via hole 113 penetrates through at least portions of the insulating layer 120, the etch stop layer 125, and the membrane 130 in the thickness direction, in addition to the substrate 110. A connection pattern 114 is formed in the via hole 113, and may be formed over the entirety of an inner surface, that is, an inner wall, of the via hole 113.

The connection pattern 114 is manufactured by forming a conductive layer on the inner surfaces of the via hole 113. For example, the connection pattern 114 is formed by depositing, applying, or filling a conductive metal such as gold or copper along the inner wall of the via hole 113. As an example, the connection pattern 114 is formed of a titanium (Ti)-copper (Cu) alloy.

The connection pattern 114 is connected to either one or both of the first electrode 140 and the second electrode 160. As an example, the connection pattern 114 penetrates through at least portions of the substrate 110, the membrane 130, the first electrode 140, and the piezoelectric layer 150, and is electrically connected to either one or both of the first electrode 140 and the second electrode 160. The connection pattern 114 formed on the inner surface of the via hole 113 is extended to the lower surface of the substrate 110, where the connection pattern 114 is connected to a substrate connection pad 115 disposed on the lower surface of the substrate 110. Therefore, the connection pattern 114 electrically connects the first electrode 140 and the second electrode 160 to the substrate connection pad 115.

The substrate connection pad 115 may be electrically connected to an external substrate that may be disposed below the bulk acoustic wave resonator 10 by a bump. The bulk acoustic wave resonator 10 performs a filtering operation on a radio frequency signal by a signal applied to the first and second electrodes 140 and 160 through the substrate connection pad 115.

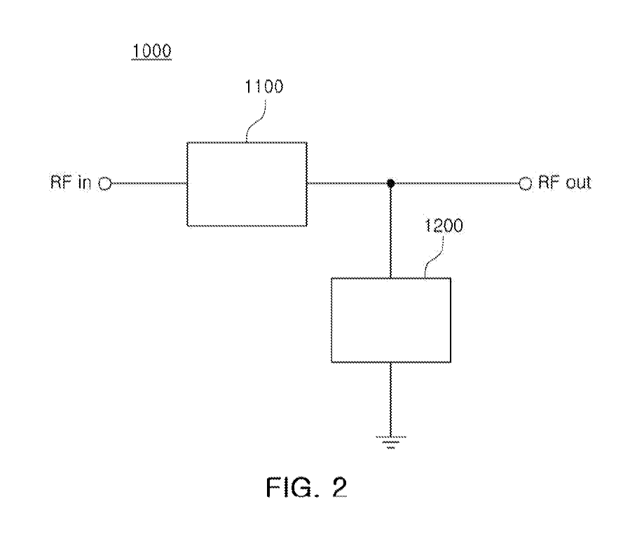

FIG. 2 is a schematic circuit diagram illustrating a filter 1000, according to an embodiment.

Referring to FIG. 2, the filter 1000 includes a series resonator group 1100 and a shunt resonator group 1200 disposed between at least one series resonator group 1100 and a ground. The filter 1000 is formed in a ladder type filter structure as illustrated in FIG. 2. Alternatively, the filter 1000 may be formed in a lattice type filter structure.

The series resonator group 1100 is connected between a signal input terminal to which an input signal RFin is input and a signal output terminal from which an output signal RFout is output. The shunt resonator group 1200 is connected between the signal output terminal and the ground. An example in which the filter 1000 includes one series resonator group 1100 and one shunt resonator group 1200 is illustrated in FIG. 2, however, multiple series resonator groups 1100 and multiple shunt resonator groups 1200 may be provided in the filter 1000. In an example in which the filter 1000 includes multiple series resonator groups 1100 and multiple shunt resonator groups 1200, the series resonator groups 1100 are connected to each other in series, and the shunt resonator groups 1200 are disposed between some nodes between the series resonator groups 1100 connected to each other in series and the ground.

Each series resonator group 1100 and shunt resonator group 1200 includes one or more bulk acoustic wave resonators 10, illustrated in FIG. 1. In embodiments in which a series resonator group 1100 or a shunt resonator group 1200 includes multiple bulk acoustic wave resonators 10, the bulk acoustic wave resonators 10 are connected to each other in either one or both of an anti-parallel manner and an anti-series manner.

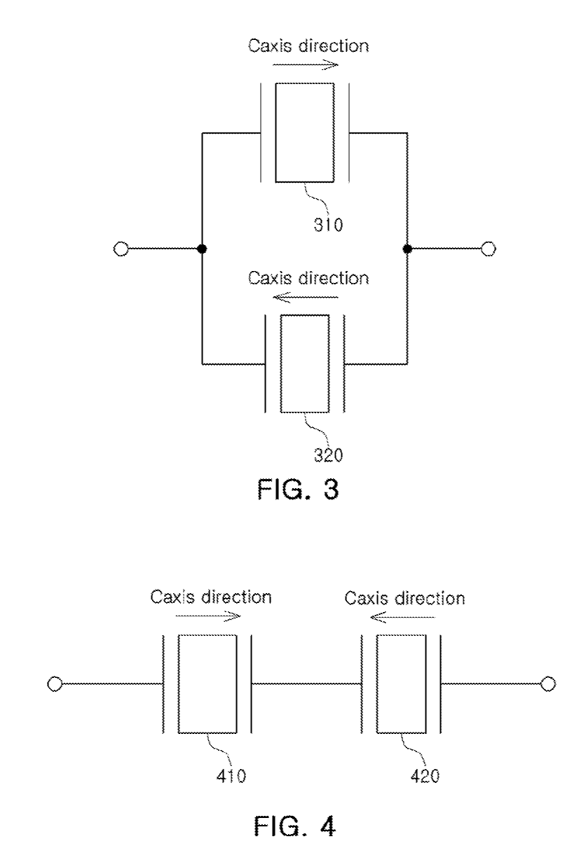

FIG. 3 is a circuit diagram illustrating two bulk acoustic wave resonators 310 and 320 connected to each other in anti-parallel, according to an embodiment. FIG. 4 is a circuit diagram illustrating two bulk acoustic wave resonators 410 and 420 connected to each other in anti-series, according to an embodiment.

Referring to FIGS. 3 and 4, the two bulk acoustic wave resonator 310 and 320 of FIG. 3 are connected to each other in anti-parallel, and the two bulk acoustic wave resonators 410 and 420 of FIG. 4 are connected to each other in anti-series. In the examples described herein, it is to be understood that the term ‘anti-parallel’ means that two bulk acoustic wave resonators are connected to each other in parallel in a state in which C axis directions of the two bulk acoustic wave resonators are opposite to each other, and the term ‘anti-series’ means that two bulk acoustic wave resonators are connected to each other in series in a state in which C axis directions of the two bulk acoustic wave resonators are opposite to each other.

When radio frequency signals are applied to the two bulk acoustic wave resonators 310 and 320 illustrated in FIG. 3, the two bulk acoustic wave resonators 310 and 320 are connected to each other in parallel in the state in which the C axis directions of the two bulk acoustic wave resonators 310 and 320 are opposite to each other, such that a vibration state of one of the two bulk acoustic wave resonators 310 and 320 is different from a vibration state of the other of the two bulk acoustic wave resonators 310 and 320. Similarly, when radio frequency signals are applied to the two bulk acoustic wave resonators 410 and 420 illustrated in FIG. 4, the two bulk acoustic wave resonators 410 and 420 are connected to each other in series in the state in which the C axis directions of the two bulk acoustic wave resonators 410 and 420 are opposite to each other, such that a vibration state of one of the two bulk acoustic wave resonators 410 and 420 is different from a vibration state of the other of the two bulk acoustic wave resonators 310 and 320. For example, in the examples of FIGS. 3 and 4, when one of the bulk acoustic wave resonators 310/410 or 320/420 is in an expansion state, the other of the bulk acoustic wave resonators 310/410 or 320/420 is in a contraction state. Therefore, non-linear characteristics of the respective bulk acoustic wave resonators 310, 320 and 410, 420 are cancelled due to opposing stimulus states of the two bulk acoustic wave resonators 310 and 320 or 410 and 420.

Recently, in accordance with a rapid increase in a demand for radio frequency communications and the development of technology, an interval between frequency bands has been reduced in order to effectively use limited frequency resources, and technology for significantly reducing interference with other bands is therefore required. In a radio frequency filter for a wireless terminal, insertion loss characteristics need to be improved in order to significantly reduce interference with other frequency bands. In addition, 2^{nd} harmonic distortion (2HD) and intermodulation distortion (IMD) phenomena interfering with frequencies in other frequency bands need to be reduced.

In a filter using a bulk acoustic wave resonator, bulk acoustic wave resonators having opposite phases and the same volume may be connected to each other in an anti-parallel or anti-series structure to improve the insertion loss characteristics and reduce the 2^{nd} harmonic distortion phenomenon and the intermodulation distortion phenomenon. However, even in this case, a pair of bulk acoustic wave resonators connected to each other in the anti-parallel structure for matching impedance of the filter become excessively small or a pair of bulk acoustic wave resonators connected to each other in the anti-series structure for matching impedance of the filter become excessively large. Such a problem may act as a limitation in improving the insertion loss characteristics and reducing the 2^{nd} harmonic distortion phenomenon and the intermodulation distortion phenomenon.

In the example filter 1000 of FIG. 2 described herein, resonators each having an anti-series relationship with respect to a pair of bulk acoustic wave resonators connected to each other in an anti-parallel structure may be connected to the pair of bulk acoustic wave resonators, respectively or resonators each having an anti-parallel relationship with respect to a pair of bulk acoustic wave resonators connected to each other in an anti-series structure may be connected to the pair of bulk acoustic wave resonators, such that sizes of the bulk acoustic wave resonators may be adjusted, the insertion loss characteristics may be improved, and the 2^{nd} harmonic distortion phenomenon and the intermodulation distortion phenomenon may be effectively reduced.

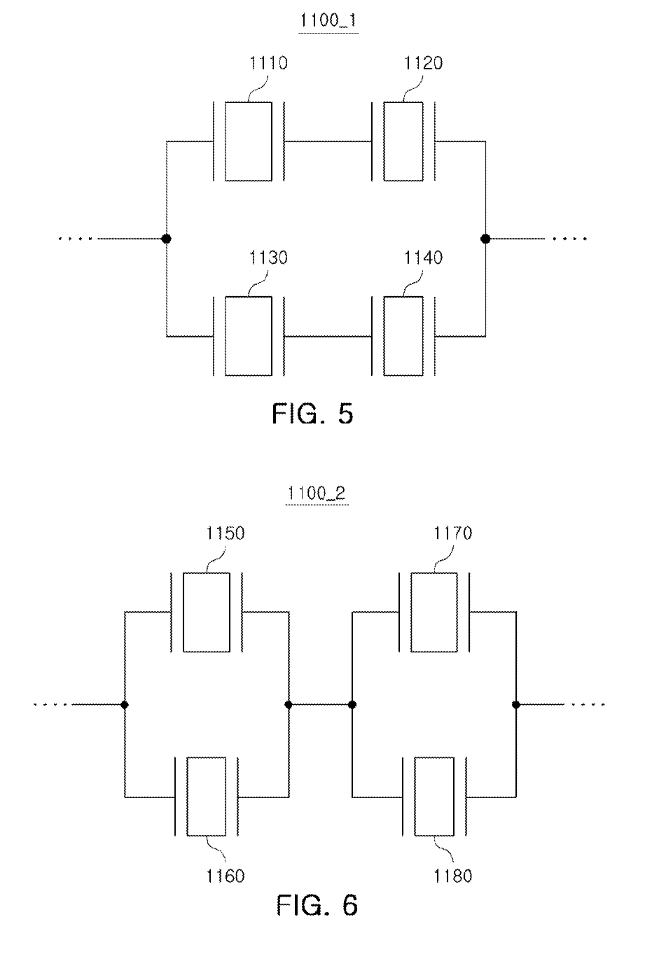

FIG. 5 is a circuit diagram illustrating a series resonator group 1100_1, according to an embodiment.

Referring to FIGS. 2 and 5, the series resonator group 1100_1 includes first to fourth series resonators 1110, 1120, 1130, and 1140. The first to fourth series resonators 1110, 1120, 1130, and 1140 are disposed between the signal input terminal to which the input signal RFin of the filter 1000 is input and the signal output terminal from which the output signal RFout is output.

The first series resonator 1110 and the second series resonator 1120 are connected to each other in series, and the third series resonator 1130 and the fourth series resonator 1140 are connected to each other in series. In addition, the first series resonator 1110 and the second series resonator 1120 are connected to the third series resonator 1130 and the fourth series resonator 1140 in parallel.

The first series resonator 1110 and the third series resonator 1130 are connected to each other in a state in which C axis directions thereof are opposite to each other, and have substantially the same size. In this example, the term ‘substantially’ means that sizes of the two resonators are the same as each other within a preset range or within an error range. The first series resonator 1110 and the third series resonator 1130 correspond to the two bulk acoustic wave resonators 310 and 320 of FIG. 3, respectively.

The first series resonator 1110 and the second series resonator 1120 have an anti-series relationship therebetween, and have substantially the same size. In addition, the third series resonator 1130 and the fourth series resonator 1140 may have an anti-series relationship therebetween, and have substantially the same size.

Table 1 is a table representing sizes and insertion loss of the respective bulk acoustic wave resonators in the Disclosed Example in which a circuit of FIG. 5 is applied to the series resonator group 1100 of the filter 1000 illustrated in FIG. 2 and Comparative Example in which a circuit of FIG. 3 is applied to the series resonator group 1100 of the filter 1000 illustrated in FIG. 2. In Table 1, it is assumed that in the Comparative Example and the Disclosed Example, configurations of the series resonator groups are different from each other, configurations of the shunt resonator groups are the same as each other, and the same frequency band is filtered.

TABLE 1

| | Size of Resonator | Insertion Loss (IL) |
|---|---|---|
| Comparative | 89.0013 μm | 1.553 dB |
| Example | | |
| Disclosed | 100.355 μm | 1.505 dB |
| Example | | |

Referring to Table 1, the second series resonator 1120 and the fourth series resonator 1140, each having an anti-series relationship with respect to the first series resonator 1110 and the third series resonator 1130, which have an anti-parallel relationship therebetween, are connected to the first series resonator 1110 and the third series resonator 1130, respectively, such that a size of either one or both of the first series resonator 1110 and the third series resonator 1130 is increased from 89.0013 μm to 100.355 μm. Since roll-off characteristics of a transmit filter are improved due to the increase in the size of the resonator, insertion loss characteristics of the filter are improved from 1.553 dB to 1.505 dB, and a 2^{nd} harmonic distortion phenomenon and an intermodulation distortion phenomenon are effectively reduced.

FIG. 6 is a circuit diagram illustrating a series resonator group 1100_2, according to another embodiment.

Referring to FIGS. 2 and 6, the series resonator group 1100_2 includes fifth to eighth series resonators 1150, 1160, 1170, and 1180. The fifth to eighth series resonators 1150, 1160, 1170, and 1180 are disposed between the signal input terminal to which the input signal RFin of the filter 1000 is input and the signal output terminal from which the output signal RFout is output.

The fifth series resonator 1150 and the sixth series resonator 1160 are connected to each other in parallel, and the seventh series resonator 1170 and the eighth series resonator 1180 are connected to each other in parallel. In addition, the fifth series resonator 1150 and the sixth series resonator 1160 are connected to the seventh series resonator 1170 and the eighth series resonator 1180 in series.

The fifth series resonator 1150 and the seventh series resonator 1170 are connected to each other in a state in which C axis directions thereof are opposite to each other, and have substantially the same size. The fifth series resonator 1150 and the seventh series resonator 1170 correspond to the two bulk acoustic wave resonators 410 and 420 of FIG. 4, respectively. The fifth series resonator 1150 and the sixth series resonator 1160 have an anti-parallel relationship therebetween, and have substantially the same size. The seventh series resonator 1170 and the eighth series resonator 1180 have an anti-parallel relationship therebetween, and have substantially the same size.

Table 2 is a table representing sizes and insertion loss of the respective bulk acoustic wave resonators in the Disclosed Example in which a circuit of FIG. 6 is applied to the series resonator group 1100 of the filter 10 illustrated in FIG. 2 and the Comparative Example in which a circuit of FIG. 4 is applied to the series resonator group of the filter 10 illustrated in FIG. 2. In Table 2, it is assumed that in the Comparative Example and the Disclosed Example, configurations of the series resonator groups are different from each other, configurations of the shunt resonator groups are the same as each other, and the same frequency band is filtered.

TABLE 2

| | Size of Resonator | Insertion Loss (IL) |
|---|---|---|
| Comparative | 144.627 μm | 1.415 dB |
| Example | | |
| Inventive | 120.9 μm | 1.365 dB |
| Example | | |

Referring to Table 2, the sixth series resonator 1160 and the eighth series resonator 1180, each having an anti-parallel relationship with respect to the fifth series resonator 1150 and the seventh series resonator 1170, which have an anti-series relationship therebetween, are connected to the fifth series resonator 1150 and the seventh series resonator 1170, respectively, such that a size of one of the fifth series resonator 1150 and the seventh series resonator 1170 is decreased from 144.627 μm to 120.9 μm. Since impedance matching is improved due to the decrease in the size of the resonator, insertion loss characteristics of the filter are improved from 1.415 dB to 1.365 dB, and a 2^{nd} harmonic distortion phenomenon and an intermodulation distortion phenomenon may be effectively reduced.

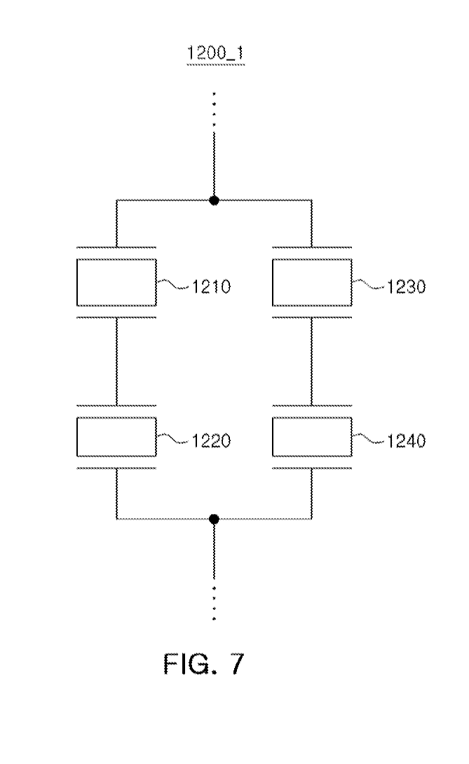

FIG. 7 is a circuit diagram illustrating a shunt resonator group 1200_1, according to an embodiment.

Referring to FIGS. 2 and 7, the shunt resonator group 1200_1 includes first to fourth shunt resonators 1210, 1220, 1230, and 1240. The first to fourth shunt resonators 1210, 1220, 1230, and 1240 are disposed between the signal output terminal from which the output signal RFout is output and the ground or between the nodes between the series resonator groups and the ground.

The first shunt resonator 1210 and the second shunt resonator 1220 are connected to each other in series, and the third shunt resonator 1230 and the fourth shunt resonator 1240 are connected to each other in series. In addition, the first shunt resonator 1210 and the second shunt resonator 1220 are connected to the third shunt resonator 1230 and the fourth shunt resonator 1240 in parallel.

The first shunt resonator 1210 and the third shunt resonator 1230 are connected to each other in a state in which C axis directions thereof are opposite to each other, and have substantially the same size. The first shunt resonator 1210 and the third shunt resonator 1230 correspond to the two bulk acoustic wave resonators 310 and 320 of FIG. 3, respectively. In this example, the first shunt resonator 1210 and the second shunt resonator 1220 have an anti-series relationship therebetween, and have substantially the same size. The third shunt resonator 1230 and the fourth shunt resonator 1240 have an anti-series relationship therebetween, and have substantially the same size.

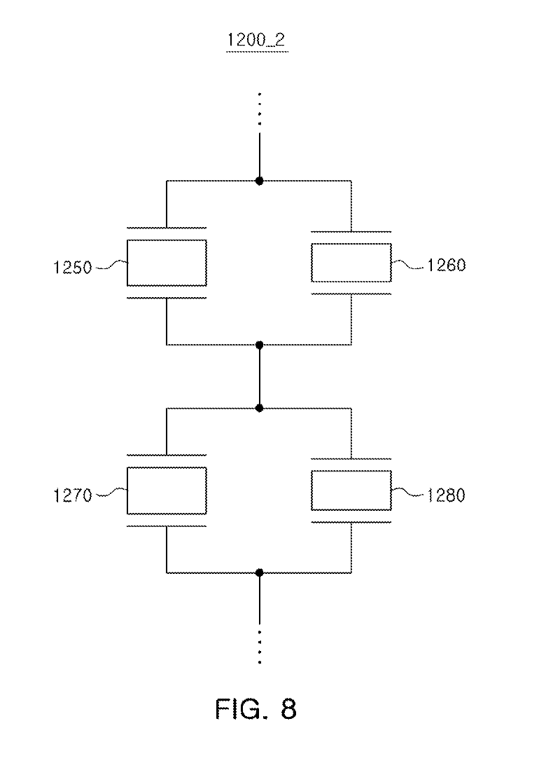

FIG. 8 is a circuit diagram illustrating a shunt resonator group 1200_2, according to another embodiment.

Referring to FIGS. 2 and 8, the shunt resonator group 1200_2 includes fifth to eighth shunt resonators 1250, 1260, 1270, and 1280. The fifth to eighth shunt resonators 1250, 1260, 1270, and 1280 are connected between the signal input terminal to which the input signal RFin of the filter 1000 is input and the signal output terminal from which the output signal RFout is output.

The fifth shunt resonator 1250 and the sixth shunt resonator 1260 are connected to each other in parallel, and the seventh shunt resonator 1270 and the eighth shunt resonator 1280 are connected to each other in parallel. In addition, the fifth shunt resonator 1250 and the sixth shunt resonator 1260 are connected to the seventh shunt resonator 1270 and the eighth shunt resonator 1280 in series.

The fifth shunt resonator 1250 and the seventh shunt resonator 1270 are connected to each other in a state in which C axis directions thereof are opposite to each other, and have, for example, substantially the same size. The fifth shunt resonator 1250 and the seventh shunt resonator 1270 correspond to the two bulk acoustic wave resonators 410 and 420 of FIG. 4, respectively. In this example, the fifth shunt resonator 1250 and the sixth shunt resonator 1260 have an anti-parallel relationship therebetween, and have substantially the same size. The seventh shunt resonator 1270 and the eighth shunt resonator 1280 may an anti-parallel relationship therebetween, and have substantially the same size.

As set forth above, a filter according to the embodiments described herein has improved insertion loss characteristics, and reduced 2^{nd} harmonic distortion and the intermodulation distortion.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A filter comprising:
a series resonator group; and
a shunt resonator group disposed between the series resonator group and a ground,
wherein either one or both of the series resonator group and the shunt resonator group comprises
a first resonator and a second resonator connected to each other in a state in which C axis directions of the first resonator and the second resonator are opposite to each other,
a third resonator connected to the first resonator in series, and
a fourth resonator connected to the second resonator in series.

2. The filter of claim 1, wherein the first resonator and the third resonator are connected to the second resonator and the fourth resonator in parallel.

3. The filter of claim 1, wherein the first resonator and the third resonator are connected to each other in anti-series.

4. The filter of claim 3, wherein a size of the first resonator and a size of the third resonator are substantially the same.

5. The filter of claim 1, wherein the second resonator and the fourth resonator are connected to each other in anti-series.

6. The filter of claim 5, wherein a size of the second resonator and a size of the fourth resonator are substantially the same.

7. The filter of claim 1, wherein a size of the first resonator and a size of the second resonator are substantially the same.

8. The filter of claim 1, wherein the series resonator group is connected between a signal input terminal and a signal output terminal.

9. A filter comprising:
a series resonator group; and
a shunt resonator group disposed between the series resonator group and a ground,
wherein either one or both of the series resonator group and the shunt resonator group comprises
a first resonator and a second resonator connected to each other in a state in which C axis directions of the first resonator and the second resonator are opposite to each other,
a third resonator connected to the first resonator in parallel, and
a fourth resonator connected to the second resonator in parallel.

10. The filter of claim 9, wherein the first resonator and the third resonator are connected to the second resonator and the fourth resonator in series.

11. The filter of claim 9, wherein the first resonator and the third resonator are connected to each other in anti-parallel.

12. The filter of claim 11, wherein a size of the first resonator and a size of the third resonator are substantially the same.

13. The filter of claim 9, wherein the second resonator and the fourth resonator are connected to each other in anti-parallel.

14. The filter of claim 13, wherein a size of the second resonator and a size of the fourth resonator are substantially the same.

15. The filter of claim 9, wherein a size of the first resonator and a size of the second resonator are substantially the same.

16. The filter of claim 9, wherein the series resonator group is connected between a signal input terminal and a signal output terminal.
